(19) United States
(12) Patent Application Publication
(10) Pub. No.: US 2006/0156987 A1
(43) Pub. Date: Jul. 20, 2006

(54) LIFT PIN MECHANISM AND SUBSTRATE CARRYING DEVICE OF A PROCESS CHAMBER

(76) Inventors: Chien-Hsing Lai, Kao-Hsiung Hsien (TW); Ying-Yi Chang, Chia-Yi Hsien (TW); Wen-Chen Shi, Tainan Hsien (TW)

Correspondence Address: NORTH AMERICA INTELLECTUAL PROPERTY CORPORATION, P.O. BOX 506, MERRIFIELD, VA, 22116, US

(21) Appl. No.: 10/905,728

(22) Filed: Jan. 18, 2005

(51) Int. Cl. C23C 16/00

(52) U.S. Cl. 118/728

(57) ABSTRACT

A lift pin mechanism is applied to a process chamber for carrying a substrate and moving the substrate upward or downward. The mechanism includes a plurality of lift pins positioned in a plurality of through holes of a pedestal and a lift ring positioned below the lift pins. The lift pins are fixed on the lift ring perpendicularly and are smaller than the through holes so that the lift pins can move upward or downward in the through holes.

### BACKGROUND OF INVENTION

1. Field of the Invention

The invention relates to a lift pin mechanism, and more particularly, to a lift pin mechanism applied to a process chamber for supporting a substrate.

2. Description of the Prior Art

Semiconductor integrated circuit manufacturing generally requires that a number of different processes be applied to a wafer. Typically, each process is applied to a wafer in a different chamber dedicated to a respective process. Thus the manufacturing process involves not only a sequence of processes carried out in the respective chambers, but also transporting wafers among the processing chambers, and loading and unloading wafers into and out of the processing chambers.

In most semiconductor IC process chambers, wafer carrying devices are installed to carry wafers for performing specific fabricating processes and to provide elements for loading or unloading wafers so that the wafers can be transferred between process chambers without damages. Taking the thin film deposition process chamber as an example, it usually comprises a wafer carrying device where a wafer can be placed for performing a deposition process. Generally, the thin film deposition technology comprises physical vapor deposition (PVD) processes and chemical vapor deposition (CVD) processes. Among these processes, the deposition performance is decided according to the uniformity of the deposited thin film, which is affected by whether the wafer is positioned flatly on the wafer carrying device during the deposition process.

Please refer to FIG. 1 and FIG. 2. FIG. 1 and FIG. 2 are sectional schematic diagrams of a wafer carrying device 12 according to the prior art. The wafer carrying device 12 is installed in a process chamber 10 and comprises a pedestal 14, a pluralities of lift pins 16, a strike plate 18, and a lift driver 20. The pedestal 14 may be a heater of the process chamber 10 so that it can provide heats and evenly heat the wafer 24 through conducting the wafer 24 during a deposition process. The top surface of the pedestal 14 is a flat plate having a plurality of through holes 22, wherein the lift pins 16 are positioned in the through holes 22 respectively. Each lift pin 16 comprises a flat top end for supporting the wafer 24. The strike plate 18 is driven by a lift driver 20 so that the strike plate 18 can move upward or downward.

For performing a process, the wafer 24 may be transferred into the process chamber 10 by a robot (not shown), and then the lift driver 20 drives the strike plate 18 upward for pushing the lift pins 16 to move upward through the through holes 22. Therefore, the lift pins 16 contact the wafer 24 and lift up the wafer 24 from the robot. The robot then moves out of the process chamber 10 to finish transferring the wafer 24. On the other hand, for loading the wafer 24 on the wafer carrying device 12, the lift driver 20 drives the strike plate 18 to move downward so that the lift pins 16 also move downward consequently for positioning the wafer 24 on the surface of the pedestal 14, as shown in FIG. 2. After the wafer 24 is loaded on the pedestal 14, the thin film deposition can be performed.

Please refer to FIG. 3, which is a magnified view of a lift pin 16 and a through hole 22 shown in FIG. 2. The lift pin 16 comprises a head portion 16a and a shaft portion 16b, wherein the shaft portion 16b is a cylinder and usually has a diameter of about 0.149 inches. In addition, the head portion 16a is set on the outside of the top end of the shaft portion 16b and has a flat top surface for supporting the wafer 24.

Referring to FIGS. 1 and 2, in the wafer carrying device 12 according to the prior art, when the lift driver 20 drives the strike plate 18 to go downward, the strike plate 18 will separate from the lift pins 16 gradually, and the lift pins 16 will fall downward resulted from self-weights so that the wafer 24 will be moved down to the pedestal 14 accordingly. However, a clean gas containing fluorine will be introduced into the process chamber 10 for cleaning the chamber wall of the process chamber 10, which produces fluorine radicals, and the lift pins 16 are usually formed by ceramic materials, such as aluminum oxide (Al₂O₃), which will react with fluorine radicals to produce fluoride aluminums 26 (such as AlF₃) under a high temperature of 450-600° C. during a period time of the thin film deposition. The chemical reaction equation is as below:
2Al₂O₃+12F*→4AlF₃+3O₂

Since the produced fluoride 26 will adhere on the lift pins 16, the shaft portions 16b of the lift pins 16 become thicker and may block the through holes 22 so that the lift pins 16 cannot move smoothly. When the lift pins 16 do not move downward smoothly, the wafer 24 will no be flatly loaded on the pedestal 14 resulting in unevenly thin film deposition. Moreover, when the fluoride 26 on the shaft portion 16b is thicker to a specific thickness, such as 0.15 inches, the shaft portion 16b easily rubs against the through holes 22 and block the through holes 22 resulting in lift pin 16 broken and that makes the wafer 24 fall down to cause damages. Therefore, the manufacturer has to stop the thin film deposition process unscheduled to clean the fluoride 26 from the lift pins 16. In a worst situation, the lift pins 16 have to be cleaned after performing the deposition process for every two wafers 24. Accordingly, the fabrication cost and efficiency are seriously impaired.

For solving the above-mentioned problem, smaller shaft portions are adopted for the lift pins 16. Please refer to FIG. 4, which is a magnified view of another kind of lift pin 16 and through hole 22 according to the prior art. The shaft portion 16b of the lift pin 16 has a smaller diameter, such as 0.139 inches. Accordingly, even when fluoride 26 adhere on the lift pin 16, the mobility of the lift pin 16 would not be influenced immediately, so that the interval of cleaning the fluoride 26 from the lift pin 16 could be extended. However, there occurs another problem that the shaft portion 16b is too thin to stand vertically on the strike plate 18 when the strike plate 18 pushes the lift pin 16 to move upward or downward, which causes shaft portion 16b may sway resulting in misalignment of the wafer 24.

Accordingly, how to improve the mechanism of the lift pins 16 to make the lift pins 16 evenly and steadily support the wafer 24 to move upward or downward and to position the wafer 24 accurately on a predetermined position of the pedestal 14 is still an important issue.

### SUMMARY OF INVENTION

It is therefore a primary objective of the claimed invention to provide a lift pin mechanism and a wafer carrying device having a lift ring to solve the above-mentioned problem.

According to the claimed invention, the wafer carrying device comprises a pedestal for carrying a substrate, a lift ring positioned below the pedestal movably, a pluralities of lift pins positioned through the pedestal, and a strike plate. The lift pins are fixed to the lift ring so that all the lift pins can move upward or downward with a direction perpendicular to the lift ring at the same time. The strike plate is positioned below the lift pins and the lift ring, and can move upward or downward to push the bottom of the lift pins or the lift ring to make the lift pins move upward or downward consequently.

Accordingly to the claimed invention, the lift pin mechanism for applying to a process chamber for moving a substrate upward or downward comprises a plurality of lift pins and a lift ring. The lift pins is positioned through pluralities of corresponding through holes of a pedestal, wherein the diameter of the lift pins is smaller than the aperture of the through holes, so that the lift pins can move upward or downward through the through holes. The lift ring is positioned below the lift pins and fixed the bottom ends of the lift pins to make the lift pins perpendicular to the lift ring.

It is an advantage of the claimed invention that the lift ring is positioned below the lift pins for fixing the bottom ends of the lift pins, so that the shaft portions of the lift pins can move upward or downward in a direction perpendicular to the pedestal to ensure the that the wafer on the lift pins can be moved downward evenly. In addition, since the lift ring can fix the direction of the shaft portions of the lift pins, the diameter of the shaft portions used can be smaller than the shaft portions in the prior art in order to avoid the lift pins rub against the through holes resulted from the fluoride adhering on the surface of the lift pins.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 and FIG. 2 are sectional schematic diagrams of a wafer carrying device 12 according to the prior art.

FIG. 3 is a magnified view of a lift pin and a through hole shown in FIG. 2.

FIG. 4 is a magnified view of another kind of lift pin and through hole according to the prior art.

FIG. 5 is a sectional schematic diagram of a substrate carrying device according to the present invention.

FIG. 6 is a magnified view of a lift pin and a lift ring shown in FIG. 5.

FIG. 7 is a schematic diagram of a lift pin mechanism according to the present invention.

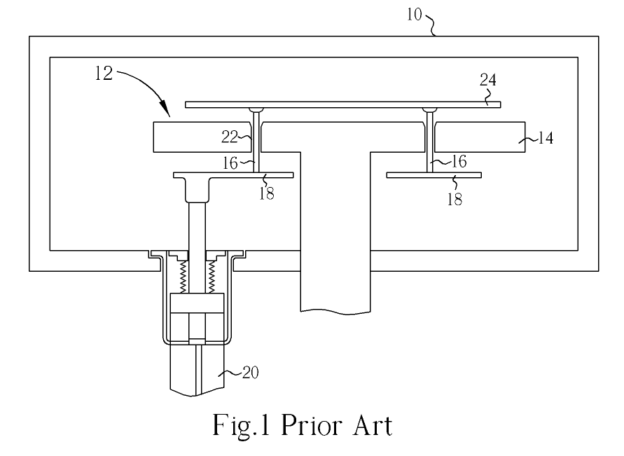

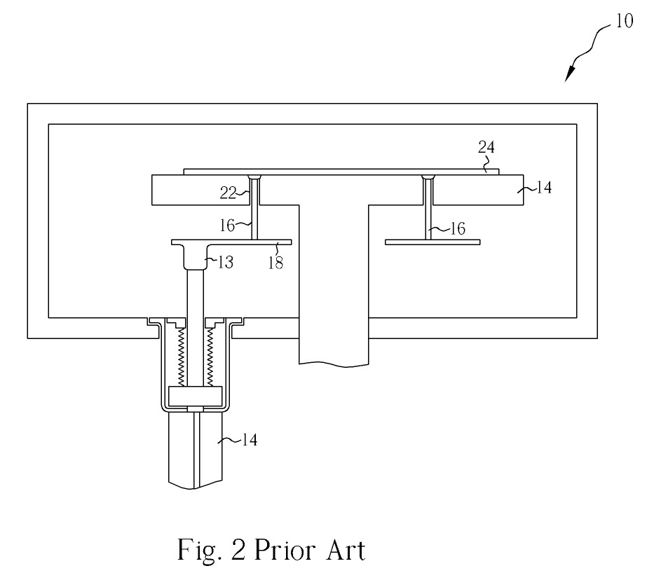

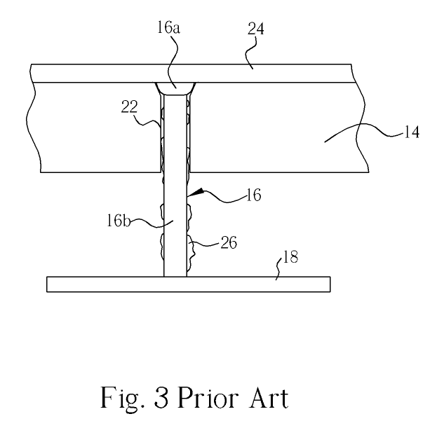

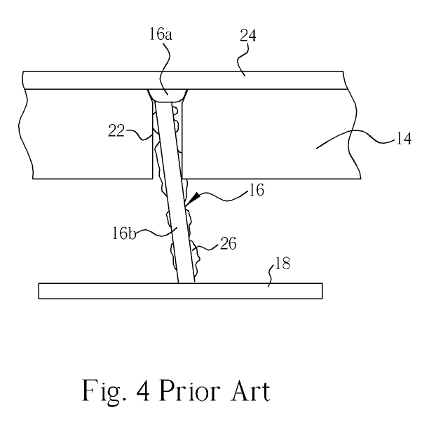

### DETAILED DESCRIPTION

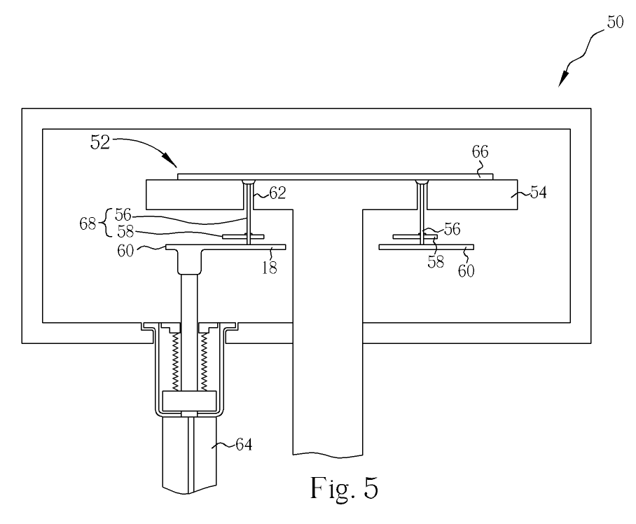

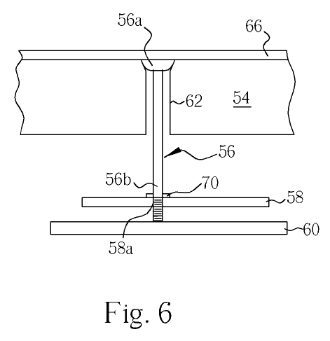

Please refer to FIGS. 5-6. FIG. 5 is a sectional schematic diagram of a substrate carrying device 52 according to the present invention, and FIG. 6 is a magnified view of a lift pin 56 and a lift ring 58 shown in FIG. 5. The substrate carrying device 52 is applied to a process chamber 50 of a semiconductor fabrication. In this embodiment, the process chamber 50 is an atmospheric pressure CVD (APCVD) process chamber or a low pressure CVD (LPCVD) process chamber for performing a CVD process to the wafer 66 under the pressure of 1 atm or less 1 atm. Furthermore, the substrate carrying device 52 is a wafer carrying device, and comprises a pedestal 54 being a heater of the process chamber 50 for carrying the wafer 66 and supplying heats during a CVD process. During the interval of performing the CVD processes, a cleaning gas containing fluorine, such as nitrogen trifluoride (NF₃), carbon tetrafluoride (CF₄), or perfluoro ethane (C₂F₆), is introduced into the process chamber 50 to produce fluorine radicals for cleaning the wall of the process chamber 50.

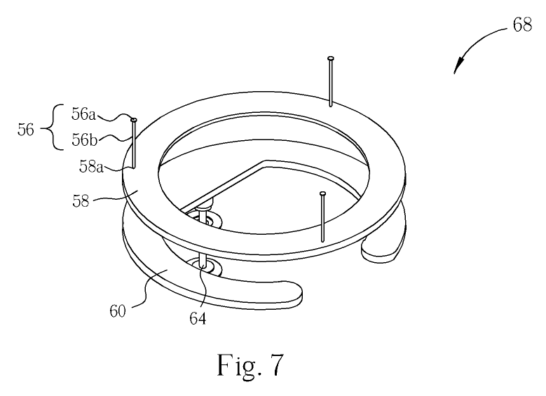

The substrate carrying device 52 further comprises a plurality of lift pins 56, a lift ring 58, a strike plate 60, and a lift driver 64. Please refer to FIG. 7, which is a schematic diagram of a lift pin 56, the lift ring 58, the strike plate 60, and the lift driver 64 shown in FIG. 5, wherein the lift pins 56 and the lift ring 58 compose a lift pin mechanism 68 installed in the substrate carrying device 50. In this embodiment, the lift pin mechanism 68 comprises at least three lift pins 56 for evenly supporting the wafer 66. The lift pins 56 are composed of a ceramic material, such as aluminum oxide. As the above description, since the temperature of the process chamber 50 is higher than 450° C. during the CVD process, aluminum oxide will react with the residual cleaning gas to produce fluoride adhering to the surface of the lift pins 56.

In addition, each lift pin 56 is movably positioned through a corresponding through hole 62 of the pedestal 54, and has a head portion 56a and a shaft portion 56b. The head portion 56a has a flat top surface for supporting the wafer 66 and is set on the outside surface of the top end of the shaft portion 56b. The shaft portion 56b is a thin cylinder, whose diameter may less than or equal to ¾ aperture of the through holes 62, wherein the preferable diameter of the shaft portion 56b is about 0.12 inches.

The lift ring 58 is a flat ring or a flat plate having pluralities of screw holes 58a for screwing and fixing the lift pins 56. Furthermore, for firmly fixing the lift pins 56 in the lift ring 58, the lift ring 58 may selectively further comprise a plurality of screw nuts 70 to fix the lift pins 56 in the screw holes 58a. The strike plate 60 is also a flat ring or a flat plate connected to a lift driver 64. The strike plate 60 can be driven by the lift driver 64 so as to move upward or downward. When the strike plate 60 is driven by the lift driver 64 to go upward, the strike plate 60 will push the bottom ends of the lift pins 56 to move the lift pins 56 upward. Similarly, in order to load the wafer 66 supported by the lift pins 56 on the pedestal 54, the lift driver 64 will drive the strike plate 60 to move downward, and therefore the lift pins 56 will also move downward because their self-weights until the wafer 66 contacts the surface of the pedestal 54. Since the bottom ends of the lift pins 56 are fixed in the lift ring 58, the lift pins 56 are kept vertically (perpendicular to the surface of the pedestal 54) whether the lift pins 56 move upward or downward. Accordingly, the wafer 66 supported by the lift pins 56 can be moved evenly and loaded evenly on the pedestal 54.

It should be noted that the shaft portions 56b adopted in the present invention has a smaller diameter than that in the prior art because the lift ring 58 can fix the lift pins 56 to keep the lift pins 56 vertically move upward or downward, which means the shaft portions 56b of the lift pins 56 will not sway during moving resulted in misalignment of the wafer. In a preferable embodiment of the present invention, the diameter of the shaft portion 56b may less than or equal to the ¾ aperture of the through holes 62. In a more preferable embodiment, the diameter of the shaft portion 56b is 0.12 inches. Although the material of the lift pins 56 may still react with the cleaning gas to produce fluoride adhering to the lift pins 56 and thickening the shaft portions 56b, the thickened shaft portions 56b are still not thick enough to block the through holes 62 since the shaft portions 56b themselves are very thin. Therefore, the problem of the lift pins 56 rubbing against the through holes 62 or block the through holes 62 to cause the lift pins 56 cannot move smoothly can be avoided. Accordingly, number of times to stop the CVD processes to clean the lift pins 56 can be reduced.

In this embodiment, the bottom ends of the lift pins 56 protrude from the lift ring 58. Therefore, when the strike plate 60 is driven by the sift driver 64 to move upward, the strike late 60 will contact the bottom ends of the lift pins 56 to move the lift ring 58 and the lift pins 56 upward. On the other hand, in another embodiment of the present invention, the bottom ends of the lift pins 56 are fixed inside the lift ring 58. Accordingly, when the strike plate 60 move upward, it will contact the lift ring 58 to indirectly move the lift pins 56 upward. Furthermore, the method of fixing the lift pins 56 to the lift ring 58 is not limited through screwing introduced in this embodiment of the present invention and may include other way to vertically fix the lift pins 56 on the lift ring 58.

According to the spirit of the present invention, it should be noted that it is not advised to fix the lift pins 56 to the strike plate 60 to replace the lift ring 58. The reason is the lift pins 56 will not have flexible space to align the wafer 66 on the pedestal 54 if the lift pins 56 are directly fixed on the strike plate 60.

In contrast to the prior art, the present invention substrate carrying device has a specific lift pin mechanism having a lift ring to make the lift pins move upward or downward vertically without swaying, so that the lift pins can support a substrate evenly and load the substrate evenly on the pedestal with supporting an alignment function. In addition, since the lift ring can fix direction of the shaft portions of the lift pins, the diameter of the shaft portion adopted can be smaller than that in the prior art provided that the fluoride adhering on the shaft portions would not block the through holes or affect the movement of the lift pins in the pedestal. Therefore, the number of times to stop the CVD process to clean the lift pins can be reduced, and the fabrication efficiency and cost can be improved.

Moreover, the present invention substrate carrying device is not limited to applied to the thin film deposition process chamber or semiconductor process chambers, any other process chambers have a need to transfer a substrate or move a substrate upward or downward can adopt the substrate carrying device or the lift pin mechanism according to the present invention. For example, the present invention may be utilized in a liquid crystal display (LCD) process chamber for loading or unloading a glass substrate of an LCD to smoothly move the glass substrate upward or downward without damages.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A substrate carrying device comprising:
a pedestal for carrying a substrate;
a lift ring movably positioned below the pedestal;
a plurality of lift pins positioned through the pedestal, whose bottom ends are fixed by the lift ring, so that the lift pins are capable of moving upward or downward in a direction perpendicular to the surface of the lift ring; and
a strike plate positioned below the lift pins, wherein the strike plate is capable of moving upward or downward and pushing the bottom ends of the lift pins or the lift ring to make the lift pins move upward or downward.

2. The substrate carrying device of claim 1, further comprising a lift driver for driving the strike plate to move upward or downward.

3. The substrate carrying device of claim 1, wherein the pedestal comprises a plurality of through holes, and each of the lift pins is movably positioned in one of the through holes.

4. The substrate carrying device of claim 1, wherein each of the lift pins has a head portion and a shaft portion, wherein the top of the shaft portion is connected to the bottom of the head portion, and the head portion is used for supporting the substrate.

5. The substrate carrying device of claim 4, wherein the diameter of the shaft portions is less than or equal to 0.12 inches.

6. The substrate carrying device of claim 1, wherein the lift ring is a flat and circular ring.

7. The substrate carrying device of claim 1, wherein the bottom ends of the lift pins are screwed in the lift ring.

8. The substrate carrying device of claim 7, wherein the lift ring comprises a plurality of screw holes for screwing and fixing the lift pins.

9. The substrate carrying device of claim 1, wherein the lift pins are positioned through the lift ring, so that the bottom ends of the lift pins protrude from a bottom surface of the lift ring.

10. The substrate carrying device of claim 1 comprising at least three of the lift pins for evenly supporting the substrate.

11. The substrate carrying device of claim 1, wherein the substrate is a wafer.

12. The substrate carrying device of claim 1, wherein the substrate carrying device is applied to a semiconductor process chamber.

13. The substrate carrying device of claim 11, wherein the semiconductor process chamber is a thin film deposition process chamber.

14. The substrate carrying device of claim 13, wherein the thin film deposition process chamber is a physical vapor deposition (PVD) process chamber or a chemical vapor deposition (CVD) process chamber.

15. The substrate carrying device of claim 14, wherein a temperature of the thin film deposition process chamber is greater than 450° C. during a thin film deposition process.

16. The substrate carrying device of claim 14, wherein the thin film deposition process chamber is an atmospheric pressure CVD (APCVD) process chamber or a low pressure CVD (LPCVD) process chamber.

17. The substrate carrying device of claim 1, wherein the lift pins are composed of a ceramic material.

18. The substrate carrying device of claim 17, wherein the ceramic material is aluminum oxide (Al₂O₃).

19. The substrate carrying device of claim 1, wherein the pedestal is a heater.

20. A lift pin mechanism applied to a process chamber for supporting a substrate and moving the substrate upward or downward, the lift pin mechanism comprising:
a plurality of lift pins positioned through a plurality of corresponding through holes of a pedestal, wherein the diameter of the lift pins is less than the aperture of the through holes, so that the lift pins are capable of moving upward or downward through the through holes; and
a lift ring positioned below the lift pins, the lift pins being fixed perpendicularly to the lift ring.

21. The lift pin mechanism of claim 20, wherein the process chamber comprises a strike plate positioned below the lift ring, wherein the strike plate is capable of moving upward or downward and pushes the lift pins or the lift ring to make the lift pins move upward or downward correspondingly.

22. The lift pin mechanism of claim 21, wherein the process chamber further comprises a lift driver for driving the strike plate to move upward or downward.

23. The lift pin mechanism of claim 20, wherein the diameter of the lift pins is less than or equal to ¾ of the aperture of the through holes.

24. The lift pin mechanism of claim 20, wherein the lift pins are screwed in the lift ring.

25. The lift pin mechanism of claim 24, wherein the lift ring comprises a plurality of screw holes for screwing and fixing the lift pins.

26. The lift pin mechanism of claim 20, wherein the lift pins are positioned through the lift ring, so that bottom ends of the lift pins protrude from a bottom surface of the lift ring.

27. The lift pin mechanism of claim 20, wherein the lift pin mechanism comprises at least three of the lift pins for evenly supporting the substrate.

28. The lift pin mechanism of claim 20, wherein the lift ring is a flat ring or a plate.

29. The lift pin mechanism of claim 20, wherein the substrate is a wafer.

30. The lift pin mechanism of claim 20, wherein the lift pin mechanism is installed in a semiconductor process chamber.

31. The lift pin mechanism of claim 30, wherein the semiconductor process chamber is a thin film deposition process chamber.

32. The lift pin mechanism of claim 31, wherein the thin film deposition process chamber is a PVD process chamber or a CVD process chamber.

33. The lift pin mechanism of claim 32, wherein a temperature of the thin film deposition process chamber is greater than 450° C. during a thin film deposition process.

34. The lift pin mechanism of claim 32, wherein the thin film deposition process chamber is an APCVD process chamber or a LPCVD process chamber.

35. The lift pin mechanism of claim 20, wherein the lift pins are composed of a ceramic material.

36. The lift pin mechanism of claim 35, wherein the ceramic material is aluminum oxide.

37. The lift pin mechanism of claim 20, wherein the pedestal is a heater.
